(19) United States
(12) Patent Application Publication
(10) Pub. No.: US 2022/0320457 A1
(43) Pub. Date: Oct. 6, 2022

(54) DISPLAY DEVICE

(71) Applicant: Sharp Kabushiki Kaisha, Sakai City, Osaka (JP)

(72) Inventor: Takashi MATSUI, Sakai City (JP)

(21) Appl. No.: 17/625,805

(22) PCT Filed: Jul. 12, 2019
(86) PCT No.: PCT/JP2019/027786

§ 371 Date: Jan. 10, 2022

(51) Int. Cl. H01L 51/52; H01L 51/00; H01L 27/32

(52) U.S. Cl. CPC H01L 51/524; H01L 51/0097; H01L 27/3244

(57) ABSTRACT

A display device includes: a flexible substrate; a thin-film transistor layer; a light-emitting element layer; a sealing layer; a display region including a plurality of pixels; a frame region provided around the display region; and drive chip mounted in the frame region. The drive chip includes: a resin film provided toward the flexible substrate between a plurality of input terminals and a plurality of output terminals. The resin film is rectangular in plan view.

### TECHNICAL FIELD

The disclosure relates to a display device.

### BACKGROUND ART

Patent Document 1 discloses a configuration; that is, when a flexible wiring board provided to an end of a display panel is bent, the configuration reduces the risk of the wiring to be broken on the flexible wiring board.

Patent Document 2 discloses another configuration; that is, when an electronic component is soldered to, and mounted on, a flexible wiring board, and the flexible wiring board is bent, the configuration reduces the risk of the wiring to be broken in a solder fillet formed when an electrode of the electronic component is soldered to a solder land.

Patent Document 3 discloses a touch panel including two transparent substrates and a flexible wiring board partially held between the two transparent substrates. In the touch panel, the flexible wiring board has a constant thickness to reduce the surface asperities of the flexible wiring board. The reduction in the surface asperities reduces depressions on the portions of the two transparent substrates holding the flexible wiring board therebetween.

### CITATION LIST

### Patent Literature

[Patent Document 1] Japanese Unexamined Patent Application Publication No. 2016-197178 (published on Nov. 24, 2016)

[Patent Document 2] Japanese Unexamined Patent Application Publication No. 2006-140416 (published on Jun. 1, 2006)

[Patent Document 3] Japanese Unexamined Patent Application Publication No. 2010-2989 (published on Jan. 7, 2010)

### SUMMARY

### Technical Problems

The disclosures of Patent Documents 1 to 3 can reduce the risk of broken wiring on the flexible wiring board.

However, it is difficult for the disclosures of Patent Documents 1 to 3 to overcome problems of a configuration including a film substrate, a resin layer, and a drive chip (an IC chip) wherein the drive chip is connected to the flexible wiring board using a chip-on-plastic (COP) technique.

With reference to FIG. 12, described below are the problems of the configuration in which a known drive chip 131 is connected using the COP technique.

FIG. 12(a) is a view of a schematic configuration of a known display device 100 including the drive chip 131 connected using the COP technique. FIG. 12(b), showing the display device 100 before the drive chip 131 is crimped, is a partially enlarged view of a portion A in FIG. 12(a). FIG. 12(c), showing the display device 100 after the drive chip 131 is crimped, is a partially enlarged view of the portion A in FIG. 12(a).

As can be seen in FIG. 12(a), the display device 100 includes: a resin layer 112; a film substrate 110 attached to a surface of the resin layer 112 through an adhesive layer 111; a display region provided above another surface of the resin layer 112; and a frame region provided around the display region.

An inorganic multilayer film 107 is formed in the display region and the frame region of the display device 100. The inorganic multilayer film 107 includes: a barrier layer (an inorganic moisture-proof layer); a gate insulating film layer; and a plurality of inorganic insulating film layers.

Formed above the inorganic multilayer film 107 in the display region are a source-drain line SH′ including a source electrode and a drain electrode; an organic EL element layer 105; and a sealing layer 106. Formed above the inorganic multilayer film 107 in the frame region are: a plurality of external signal input lines TM′1 (not-shown) to TM′m including terminal units; and a plurality of routed lines TW′1 (not-shown) to TW′n electrically connected to a source-drain line SH′ in the display region. A flexible wiring board 134 is provided on the terminals of the external signal input lines TM′1 to TM′m.

Through an anisotropic conductive film 132, the drive chip 131 is mounted on the routed lines TW′1 to TW′n and the external signal input lines TM′1 to TM′m in the frame region. The drive chip 131 includes a plurality of input terminals 131IB1 to 131IBm each positioned above a corresponding one of the external signal input lines TM′1 to TM′m. The input terminals 131IB1 to 131IBm are connected to the respective external signal input lines TM′1 to TM′m through an anisotropic conductive material 133 included in the anisotropic conductive film 132. The drive chip 131 includes a plurality of output terminals 131OB1 to 131OBn each positioned above a corresponding one of the routed lines TW′1 to TW′n. The output terminals 131OB1 to 131OBn are electrically connected to the respective routed lines TW′1 to TW′n through the anisotropic conductive material 133.

FIG. 12(b) shows the drive chip 131 before crimped. Here, in a region B (a portion B) between the input terminal 131IBm and the output terminals 131OBn and 131OBn-1, the adhesive layer 111, the resin layer 112, and the inorganic multilayer film 107 formed above the film substrate 110 are all flat.

FIG. 12(c) shows the drive chip 131 after crimped. When the drive chip 131 is crimped, a downward pressure is exerted on a region including the input terminal 131IBm and the output terminals 131OBn and 131OBn-1. Because of this downward pressure, the adhesive in the adhesive layer 111 could flow from the region below the input terminal 131IBm and the output terminals 131OBn and 131OBn-1 toward another region. FIG. 12(c) shows arrows indicating directions of the adhesive flowing. The flow of the adhesive raises the adhesive layer 111, the resin layer 112, and the inorganic multilayer film 107 formed above the film substrate 110 in the portion B of FIG. 12(c). Although not shown, the film substrate 110 could rise if the film substrate 110 is soft.

Recent years have seen a request to the drive chip 131 to be thinner in size and higher in quality. Even if all the adhesive layer 111, the resin layer 112, the inorganic multilayer film 107, and the film substrate 110 rise while the request is met, the display device still has to maintain its quality high. Considering such a request, no known documents have been found to disclose a technique in the above viewpoint.

In view of the above problems, the disclosure is intended to provide a display device achieving high quality.

### Solution to Problems

In order to solve the above problems, a display device according to an aspect of the present disclosure includes: a flexible substrate; a thin-film transistor layer provided above the flexible substrate; a light-emitting element layer including a first electrode, a functional layer, and a second electrode; a sealing layer; a display region including a plurality of pixels; a frame region provided around the display region; and an electronic component mounted in the frame region. The electronic component includes: a plurality of input bumps inputting signals; and a plurality of output bumps outputting the signals. The input bumps and the output bumps are arranged in a longitudinal direction of the electric component. The frame region includes: a plurality of input terminal electrodes each electrically connected to a corresponding one of the input bumps through an anisotropic conductive film; and a plurality of output terminal electrodes each electrically connected to a corresponding one of the output bumps through the anisotropic conductive film. The electronic component includes a resin film provided toward the flexible substrate between the input bumps and the output bumps. The resin film is rectangular in plan view.

### Advantageous Effects of Disclosure

An aspect of the disclosure can provide a display device with high quality.

### BRIEF DESCRIPTION OF DRAWINGS

FIG. 1(a) is a plan view of a flexible organic EL display device according to a first embodiment. FIG. 1(b) is a cross-sectional view of a display region in the flexible organic EL display device according to the first embodiment.

FIG. 2 shows a drive chip before crimped to a frame region NA.

FIG. 3(a) is a view of a plurality of input terminals and a plurality of output terminals in the drive chip. FIG. 3(b) is a schematic view of the flexible organic EL display device to which the drive chip is connected.

FIG. 4 is a schematic view of a resin film according to the first embodiment.

FIG. 5 is a schematic view of the resin film according to a second embodiment.

FIG. 6(a) shows an example of a texture formed on the resin film of the present disclosure. FIG. 6(b) shows another example of the texture formed on the resin film of the present disclosure.

FIG. 7 shows a case where the drive chip, according to the first embodiment and coated with the resin film, is crimped to the frame region.

FIG. 8 shows a case where the drive chip, according to the first embodiment and coated with the resin film, is subjected to a reliability test.

FIG. 9 is a schematic view of the resin film according to a third embodiment.

FIG. 10 is a schematic view of the resin film according to a fourth embodiment.

FIG. 11 is a schematic view of the resin film according to a fifth embodiment.

FIG. 12(a) is a view of a schematic configuration of a known display device including a drive chip connected using a COP technique. FIG. 12(b), showing the display device before the drive chip is crimped, is a partially enlarged view of a portion A in FIG. 12(a). FIG. 12(c), showing the display device after the drive chip is crimped, is a partially enlarged view of the portion A in FIG. 12(a).

### DESCRIPTION OF EMBODIMENTS

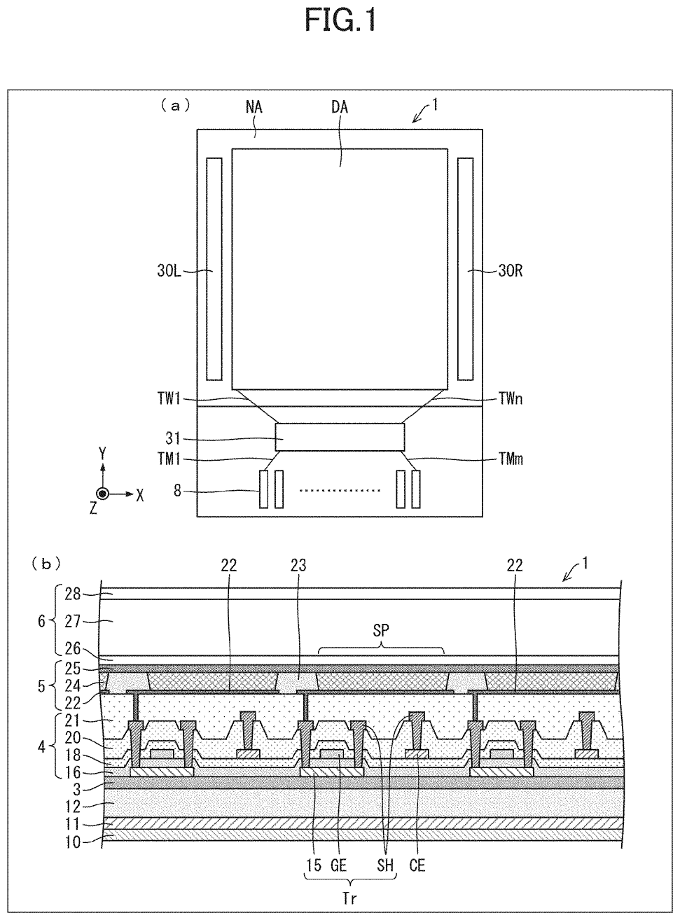

Described below are embodiments of the present disclosure, with reference to the drawings such as FIG. 1. For the sake of description, identical reference signs are used to denote identical components throughout the embodiments. Such components will not be repeatedly elaborated upon.

In the embodiments below, an organic electroluminescence (EL) element is described as an example of a display element (an optical element). However, the display element shall not be limited to the organic EL element. Alternatively, the display element may be, for example, a reflective liquid crystal display element whose luminance and/or transmittance is controlled by voltage, eliminating the need of a backlight.

The display element may also be an optical element whose luminance and/or transmittance is controlled by current. The optical element controlled by current is included in organic EL displays provided with organic light-emitting diodes (OLEDs). Moreover, the optical element controlled by current is included in such displays as EL displays and quantum-dot light-emitting diode (QLED) displays. The EL displays are, for example, inorganic EL displays provided with inorganic light-emitting diodes. The QLED displays are provided with QLEDs.

Note that the present disclosure is also applicable to a flexible display device provided with display elements other than the above display elements.

### First Embodiment

Described below is a flexible organic EL display device 1 according to a first embodiment of the present disclosure, with reference to such drawings as FIG. 1.

FIG. 1(a) is a plan view of the flexible organic EL display device 1. FIG. 1(b) is a cross-sectional view of a display region DA in the flexible organic EL display device 1.

Described below are steps for producing the flexible organic EL display device 1, with reference to FIG. 1(a) and FIG. 1(b).

First, at Step S1, a resin layer 12 (a flexible substrate) is formed on a light-transparent support substrate (e.g. a mother glass substrate) to be removed in a succeeding step and replaced with a film substrate 10. At Step S2, a barrier layer 3 is formed. At Step S3, a thin-film transistor layer (a TFT layer) 4 is formed. The TFT layer 4 includes: a plurality of external signal input lines TM1 to TMm including terminal units; and a plurality of routed lines TW1 to TWn electrically connected to a source-drain line SH of the display region DA. At Step S4, an organic EL element layer 5 is formed as a display element. The organic EL element layer 5 is a light-emitting element layer. At Step S5, a sealing layer 6 is formed. At Step S6, an upper-face film (not shown) is attached to the sealing layer 6. Note that a step to attach the upper-face film to the sealing layer 6 may be omitted as appropriate when, for example, a touch panel is provided to the sealing layer 6 through a bonding layer. At Step S7, a laser beam is emitted to a lower face of the resin layer 12 through the support substrate to reduce bonding strength between the support substrate and the resin layer 12, and the support substrate is removed from the resin layer 12.

This step is also referred to as a laser-lift-off (LLO) step. At Step S8, the film substrate 10 is attached, through an adhesive layer 11, to the face of the resin layer 12 with the support substrate removed. At Step S9, a multilayer stack including the film substrate 10, the adhesive layer 11, the resin layer 12, the barrier layer 3, the TFT layer 4, the organic EL element layer 5, the sealing layer 6, and the upper-face film is separated into a plurality of pieces. After that, a flexible wiring board (not shown) is crimped to, and mounted on, the terminals included in the external signal input lines TM1 to TMm, using an anisotropic conductive material (also referred to as an anisotropic conductive film, or an ACF). At Step S10, a drive chip 31 (an electronic component) is crimped to, and mounted on, the external signal input lines TM1 to TMm and the routed lines TW1 to TWn, using an anisotropic conductive material. At Step S11, the product has its edge folded to be finalized as the flexible organic EL display device 1. At Step S12, the flexible organic EL display device 1 undergoes an inspection for broken line, and if a broken line is found, the line is repaired.

As illustrated in FIG. 1(a), this embodiment shows an exemplary case where two gate drivers 30R and 30L are provided in a frame region NA of the flexible organic display device 1 to constitute a gate driver monolithic (GDM) circuit. That is, each of the gate drivers 30R and 30L is provided, in the frame region NA, either to the right or to the left of the display region DA. However, the gate drivers constituting the GDM circuit do not have to be provided only in the frame region NA. The gate drivers may be provided in the display region DA. Furthermore, the gate drivers do not have to constitute a GDM circuit. For example, the gate drivers may be provided externally.

Note that, when the gate drivers constitute a GDM circuit, it means that a plurality of transistors included in the gate drivers are formed of the same material as that of a plurality of transistors included in the TFT layer 4 and provided to the display region DA.

An exemplary material of the film substrate 10 includes, but not limited to, polyethylene terephthalate (PET).

An example of the adhesive layer 11 includes, but not limited to, optically clear adhesive (OCA) or optically clear resin (OCR).

Exemplary materials of the resin layer 12 include, but not limited to, polyimide resin, epoxy resin, and polyamide resin.

When the flexible organic EL display device 1 is in use, the barrier layer 3 keeps water or impurities from reaching the TFT layer 4 or the organic EL element layer 5. The barrier layer 3 can be formed of, for example, a silicon oxide film, a silicon nitride film, or a silicon oxide nitride film formed by the chemical-vapor deposition (CVD). Alternatively, the barrier layer 3 can be formed of a multilayer film including these films.

The TFT layer 4 is provided above the resin layer 12 and the barrier layer 3. The TFT layer 4 includes: a semiconductor film 15; an inorganic insulating film (a gate insulating film layer) 16 above the semiconductor film 15; a gate electrode GE above the inorganic insulating film 16; an inorganic insulating film 18 above the gate electrode GE; a capacitance line CE above the inorganic insulating film 18; an inorganic insulating film 20 above the capacitance line CE; a source-drain line SH provided above the inorganic insulating film 20 and including a source electrode and a drain electrode; and a planarization film 21 provided above the source-drain line SH.

The semiconductor film 15, the inorganic insulating film 16, the gate electrode GE, the inorganic insulating film 18, the inorganic insulating film 20, and the source-drain line SH constitute a thin-film transistor Tr (a TFT) serving as an active element.

The semiconductor film 15 is formed of, for example, low-temperature polysilicon (LTPS) or an oxide semiconductor. In FIG. 1(b), the TFT including the semiconductor film 15 as a channel is of a top gate structure. However, the TFT may be of a bottom gate structure (if, for example, the channel of the TFT is formed of an oxide semiconductor).

Each of the gate electrode GE, the capacitance electrode CE, the source-drain line SH, the external signal input lines TM1 to TMm, and the routed lines TW1 to TWn is a monolayer metal film formed of at least one of such metals as aluminum (Al), tungsten (W), molybdenum (Mo), tantalum (Ta), chromium (Cr), titanium (Ti), and copper (Cu). Alternatively, each of the electrodes and the lines is a multilayer metal film including these metals.

Each of the inorganic insulating films 16, 18, and 20 can be a silicon oxide (SiOₓ) film, a silicon nitride (SiNₓ) film, or a silicon oxide nitride film formed by, for example, the CVD. Alternatively, each of the inorganic insulating films 16, 18, and 20 can be a multilayer film including these films.

The planarization film (an interlayer insulating film) 21 can be formed of, for example, an applicable photosensitive organic material such as polyimide resin or acrylic resin.

Note that the flexible organic EL display device 1 includes a plurality of inorganic films in common between the display region DA and the frame region NA. The common inorganic films include the barrier layer 3, the inorganic insulating film 16, the inorganic insulating film 18, and the inorganic insulating film 20.

The frame region NA is disposed out of the display region DA in the flexible organic EL display device 1 illustrated in FIG. 1(a). The frame region NA includes: the gate drivers 30R and 30L; the drive chip 31; the external signal input lines TM1 to TMm; a plurality of input terminal electrodes (not shown) TMe1 to TMem each provided to a distal end of a corresponding one of the external signal input lines TM1 to TMm; the routed lines TW1 to TWn electrically connected to the source-drain line SH in the display region DA; and a plurality of output terminal electrodes (not shown) TWe1 to TWen each provided to a distal end of a corresponding one of the routed lines TW1 to TWn. When the drive chip 31 is mounted on the flexible organic EL display device 1, the input terminal electrodes TMe1 to TMem are electrically connected, through an ACF, to input bumps provided to the drive chip 31, and the output terminal electrodes TWe1 to TWen are electrically connected, through an ACF, to output bumps provided to the drive chip 31. Details of the configuration, the input bumps, and the output bumps will be described later.

The external signal input lines TM1 to TMm are electrically connected to flexible-printed-circuit (FPC) electrodes 8. Through the FPC electrodes 8, signals are input to the external signal input lines TM1 to TMm. The signals input to the external signal input lines TM1 to TMm are input into the drive chip 31 through the input terminal electrodes TMe1 to TMen and a plurality of input terminals 31IB1 to 31IBm (the input bumps) of the drive chip 31. The signals processed in the drive chip 31 are output to the display region (DA) through a plurality of output terminals 31OB1 to 31OBn (the output bumps), the output terminal electrodes TWe1 to TWen, and the routed lines TW1 to TWn.

The organic EL element layer 5 includes: an anode 22 (a first electrode) provided above the planarization film 21 and shaped into an island for each sub-pixel SP; a bank 23 covering an edge of the anode 22; an electroluminescence (EL) layer (a functional layer) 24 provided above the anode 22 and shaped into an island for each sub-pixel SP; and a cathode 25 (a second electrode) provided above the EL layer 24. The bank 23 (an anode edge cover 23) can be formed of, for example, an applicable photosensitive organic material such as polyimide resin and acrylic resin. The organic EL element layer 5, forming the display region DA, is provided above the TFT layer 4.

The EL layer 24 includes: a hole-injection layer; a hole-transport layer; a light-emission layer, an electron-transport layer; and an electron-injection layer stacked on top of another in the stated order from below. The light-emitting layer is formed by vapor deposition or ink-jet printing, and shaped into an island for each sub-pixel. The other layers can be each formed as a common layer shaped into a monolithic form. The EL layer 24 may omit one or more of the hole-injection layer, the hole-transport layer, the electron-transport layer, and the electron-injection layer.

The anode 22, which reflects light, is formed of, for example, a stack of indium tin oxide (ITO) and an alloy containing Ag. The cathode 25 can be formed of a light-transparent conductive material such as ITO and indium zinc oxide (IZO).

In the organic EL element layer 5, holes and electrons recombine together by a drive current between the anode 22 and the cathode 25, which forms an exciton. While the exciton transforms to the ground state, light is released. Since the cathode 25 is light-transparent and the anode 22 is light-reflective, the light emitted from the EL layer 24 travels upward. This is how the organic EL element layer 5 is of a top emission type.

The sealing layer 6 is transparent to light, and includes: a first inorganic sealing film 26 covering the cathode 25; an organic sealing film 27 formed above the first inorganic sealing film 26; and a second inorganic sealing film 28 covering the organic sealing film 27. The sealing layer 6 covering the organic EL element layer 5 prevents such a foreign object as water or oxygen from penetrating into the organic EL element layer 5.

An example of the first inorganic sealing film 26 and the second inorganic sealing film 28 can include a silicon oxide film, a silicon nitride film, or a silicon oxide nitride film formed by the CVD. Alternatively, the example can include a multilayer film containing these films. The organic sealing film 27 is a light-transparent organic film thicker than the first inorganic sealing film 26 and the second inorganic sealing film 28. The organic sealing film 27 can be formed of, for example, an applicable photosensitive organic material such as polyimide resin and acrylic resin.

Drive Chip 31

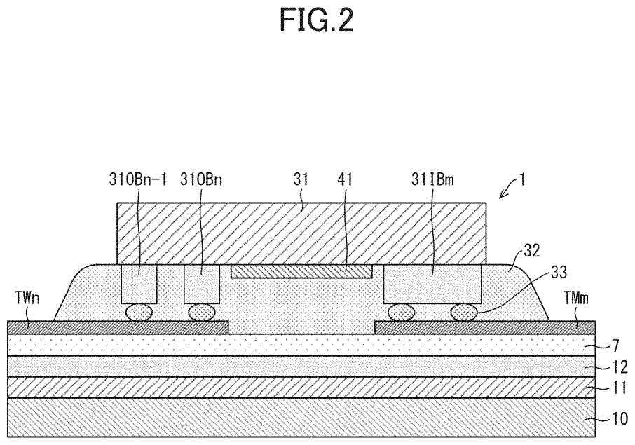

FIG. 2 shows the drive chip 31, included in the flexible organic EL display device 1, before crimped to the frame region NA.

As illustrated in FIG. 2, the input terminal 31Bm (an input bump) of the drive chip 31 is electrically connected, through an anisotropic conductive material 33, to an input terminal electrode (not-shown) of the external signal input line TMm. Moreover, each of the output terminals 31OBn and 31OBn-1 (output bumps) of the drive chip 31 is electrically connected, through the anisotropic conductive material 33, to an output terminal electrode (not shown) of a corresponding one of the routed lines TWn and TWn-1.

The drive chip 31 has a main surface provided with a resin film 41 toward an inorganic multilayer film 7. The resin film 41 is made of an elastically deformable material, such as an applicable photosensitive organic material including, for example, polyimide (PI) resin or acrylic resin. The resin film 41 will be described later.

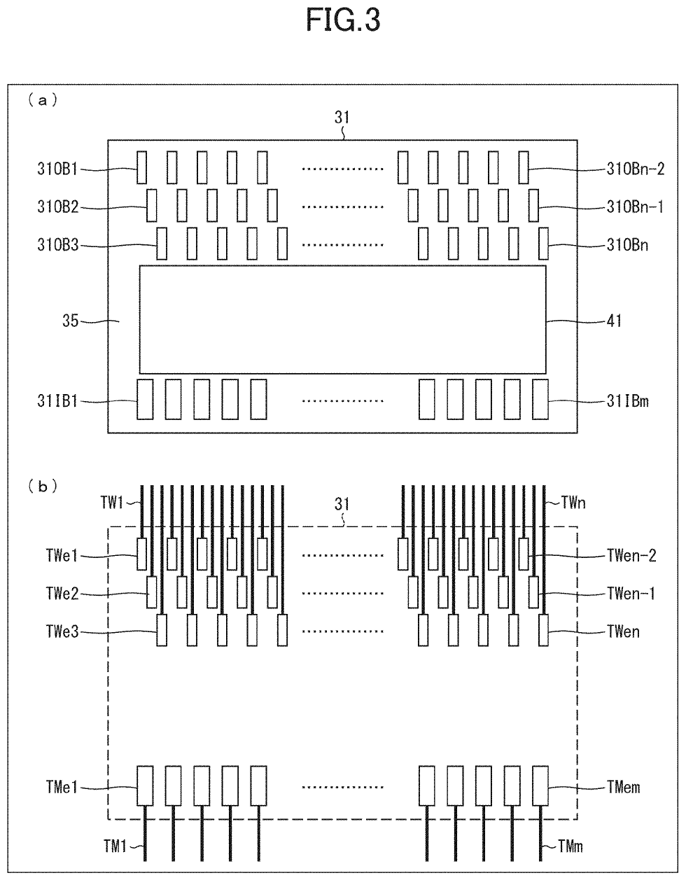

FIG. 3(a) is a view of the input terminals 31IB1 to 31IBm and the output terminals 31OB1 to 31OBn of the drive chip 31. FIG. 3(a) shows the main surface of the drive chip 31 when the drive chip 31 is observed from the inorganic multilayer film 7.

As illustrated in FIG. 3(a), the output terminals 31OB1 to 31OBn of the drive chip 31 are arranged in three rows. Because the output terminals are arranged in multiple rows, the neighboring output terminals in the same row can be spaced apart from each other at wider intervals.

FIG. 3 shows an exemplary case where the output terminals are arranged in three rows. However, the output terminals of the drive chip 31 may be arranged in one row, or in multiple rows such as two rows, or four or more rows.

As illustrated in FIG. 3(a), the input terminals 31IB1 to 31IBm of the drive chip 31 are arranged in one row. However, the input terminals 31IB1 to 31IBm may be arranged in multiple rows.

As illustrated in FIG. 3(a), the resin film 41 is provided between the input terminals 31IB1 to 31IBm and the output terminals 31OB1 to 31OBn. When the drive chip 31 is observed from the inorganic multilayer film 7, the resin film 41 is rectangular in plan view. However, the resin film 41 may be other than rectangular. On the drive chip 31, the input terminals 31IB1 to 31IBm and the output terminals 31OB1 to 31OBn are arranged in a longitudinal direction of the drive chip 31 (i.e. the X-axis direction of the X-, Y-, and Z-axes in FIG. 1(a)).

FIG. 3(b) is a schematic view of the flexible organic EL display device to which the drive chip 31 is connected. After the drive chip 31 is crimped, each of the input terminals 31IB1 to 31IBm of the drive chip 31 is positioned above an input terminal electrode of a corresponding one of the external signal input lines TM1 to TMm. Each of the output terminals 31OB1 to 31OBn of the drive chip 31 is positioned above an output terminal electrode of a corresponding one of the routed lines TW1 to TWn.

In this embodiment, as an example, the routed lines TW1 to TWn and the external signal input lines TM1 to TMm are made of, but not limited to, the same material as that of the source-drain line SH.

The output terminal electrodes TWe1 to TWen may be greater in number, and smaller in size (area) in plan view, than the input terminal electrodes TMe1 to TMem.

Resin Film 41

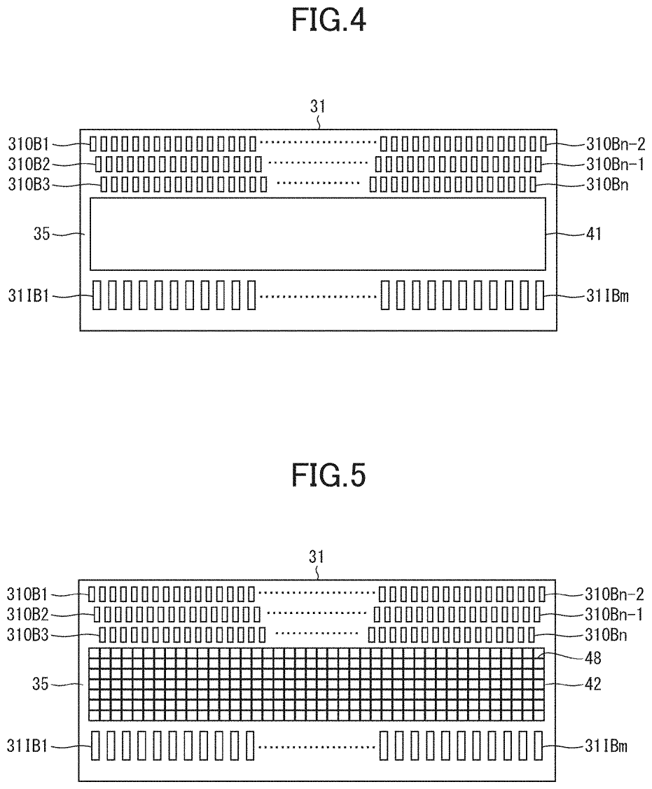

FIG. 4 is a schematic view of the resin film 41 according to the first embodiment. The resin film 41 is provided between the input terminals 31IB1 to 31IBm and the output terminals 31OB1 to 31OBn, in order to keep a circuit face 35 of the drive chip 31 from having a scratch due to an incoming foreign object. The resin film 41 has a flat surface. The circuit face 35 is provided with the input terminals 31IB1 to 31IBm and the output terminals 31OB1 to 31OBn of the drive chip 31.

Thanks to the above configuration, the circuit face 35 of the drive chip 31 is protected by the resin film 41. Hence, if the drive chip 31 is mounted in the frame region NA with a foreign object found between the drive chip 31 and the anisotropic conductive film 32, the resin film 41 can protect the circuit face 35 from the foreign object.

In the case of an organic EL display including OLEDs, for example, the input terminals 31IB1 to 31IBm and the output terminals 31OB1 to 31OBn of the drive chip 31 are small in size; that is, a size ranging from 7 to 9 μm (for an LCD, a thickness ranging from 12 to 15 μm). Hence, in the case of an organic EL display including OLEDs, the drive chip 31 is vulnerable to an incoming foreign object. Hence, when used for the organic EL display including OLEDs, the resin film 41 can effectively protect the circuit face 35 from the foreign object.

Because of the above reasons, the resin film 41 can contribute to providing the flexible organic EL display device 1 with high quality. Thus, the flexible organic EL display device 1 can be beneficially used for motor vehicles, because vehicle-mounted display devices are required to have particularly high quality. The same is true of resin films 42 to 45 to be described later.

### Second Embodiment

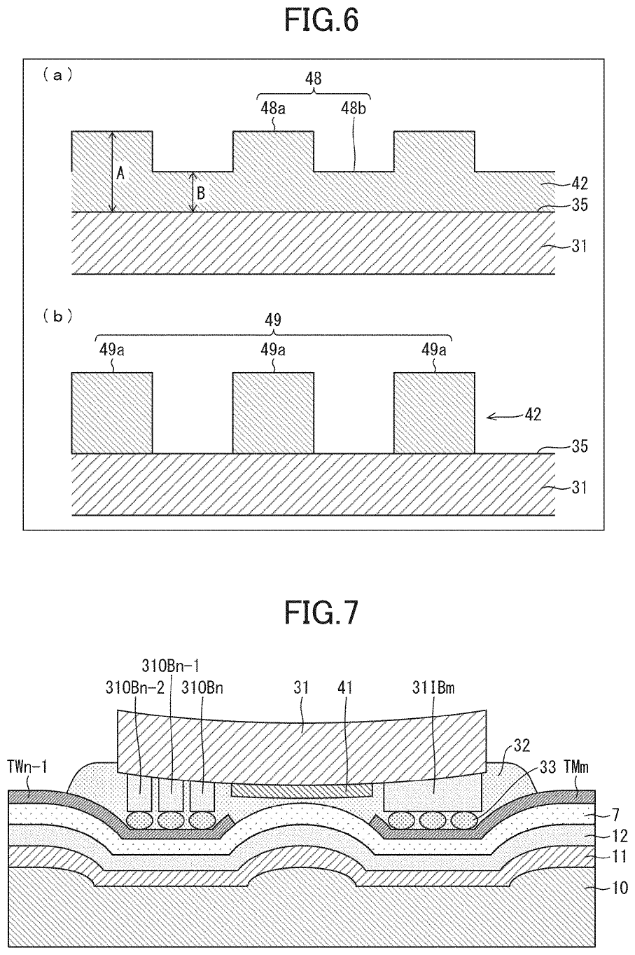

FIG. 5 is a schematic view of the resin film 42 according to the second embodiment. The resin film 42 is provided between the input terminals 31IB1 to 31IBm and the output terminals 31OB1 to 31OBn, in order to keep the circuit face 35 of the drive chip 31 from having a scratch due to an incoming foreign object. The resin film 42 has a texture 48 (slits) formed on the entire surface of the resin film 42. In other words, the resin film 42 includes a plurality of protrusions shaped into islands and provided over the whole surface of the resin film 42 in plan view. Described below is the texture 48 with reference to FIG. 6.

FIG. 6(a) shows an example of the texture 48 formed on the resin film 42 provided to the circuit face 35 of the drive chip 31. The texture 48 includes protrusions 48a and recesses 48b. The protrusions 48a and the recesses 48b are alternately arranged. The protrusions 48a and the recesses 48b may be formed integrally or separately.

In FIG. 6(a), the reference sign “A” denotes a length from a bottom face of the resin film 42 to a top face of a protrusion 48a. The reference sign “B” denotes a length from the bottom face of the resin film 42 to a top face of a recess 48b. A relationship between “A” and “B” preferably satisfies that “A-B” is A/2. In other words, each of the protrusions 48a has the protruding length (A-B), from a body of the resin film 42, of preferably ½ as long as the film thickness (A) of the resin film 42. The relationship “A/2” means approximately A/2. For example, when the “A” is designed 3 μm, the relationship “A/2” is within a variation of approximately 1 μm due to precision in a production step.

Note that, in FIG. 6(a), the top faces of the protrusions 48a are aligned at the same height. This is for the sake of description. Actually, it is difficult to align the top faces because of, for example, production errors. The same is true of the top faces of the recesses 48b. Hence, the figures “A” and “B” are numeric values in view of designing, and the “A-B” does not have to satisfy the relationship A/2 for each neighboring protrusion 48a and recess 48b.

The protrusions 48a and the recesses 48b may have any given width as long as the protrusions 48a and the recesses 48b can achieve the anchor effect to be described later.

Moreover, on the resin film 42, the texture 48 is disposed in one direction alone (the longitudinal direction or the transverse direction). In order to achieve the anchor effect more greatly, the texture 48 is preferably disposed in two directions (the longitudinal direction and the transverse direction). The same is true of a texture 49 to be described below.

FIG. 6(b) shows an example of the texture 49 formed on the resin film 42 provided to the circuit face 35 of the drive chip 31. The texture 49 includes a plurality of protrusions 49a. The protrusions 49a are spaced apart from each other, and the resin film 42 is not formed between the neighboring protrusions 49a.

As can be seen, the textures of the resin film 42 can be formed into various shapes. The same is true of, for example, a resin film 43 to be described later. Described below is an advantageous effect that the resin film 42 achieves.

FIG. 7 shows a case where the drive chip 31, according to the first embodiment and coated with the resin film 41, is crimped to the frame region NA. As described above, the resin film 41 can protect the circuit face 35 (not shown) of the drive chip 31 from a foreign object. Meanwhile, the resin film 41 has room for improvement on the points below.

Recent years have seen a request to the drive chip 31 to be thinner in size and higher in quality. When the drive chip 31 is thinner (e.g. 0.2 mm or less), the drive chip 31 is likely to be deformed to curve concavely while being crimped. FIG. 7 shows a case where heat and load are applied downward to the drive chip, and, as a result, the drive chip 31 is deformed to curve concavely.

Furthermore, when the drive chip 31 is crimped, a downward pressure is exerted on a region including the input terminals 31IB1 to 31IBm and the output terminals 31OB1 to 31OBn. Because of this downward pressure, the adhesive in the adhesive layer 11 could flow from the region below the input terminals 31IB1 to 31IBm and the output terminals 31OB1 to 31OBn toward another region. As illustrate in FIG. 7, the flow of the adhesive raises the film substrate 10, the adhesive layer 11, the resin layer 12, and the inorganic multilayer film 7 to curve convexly.

Thus, when the drive chip 31 is crimped, the drive chip 31 is deformed to curve concavely, and the film substrate 10, the adhesive layer 11, the resin layer 12, and the inorganic multilayer film 7 rise to curve convexly. Hence, the anisotropic conductive film 32 is thinner in a region near a center of the drive chip 31 than in another region. When the anisotropic conductive film 32 becomes thinner, the adhesiveness between the anisotropic conductive film 32 and the drive chip 31 decreases.

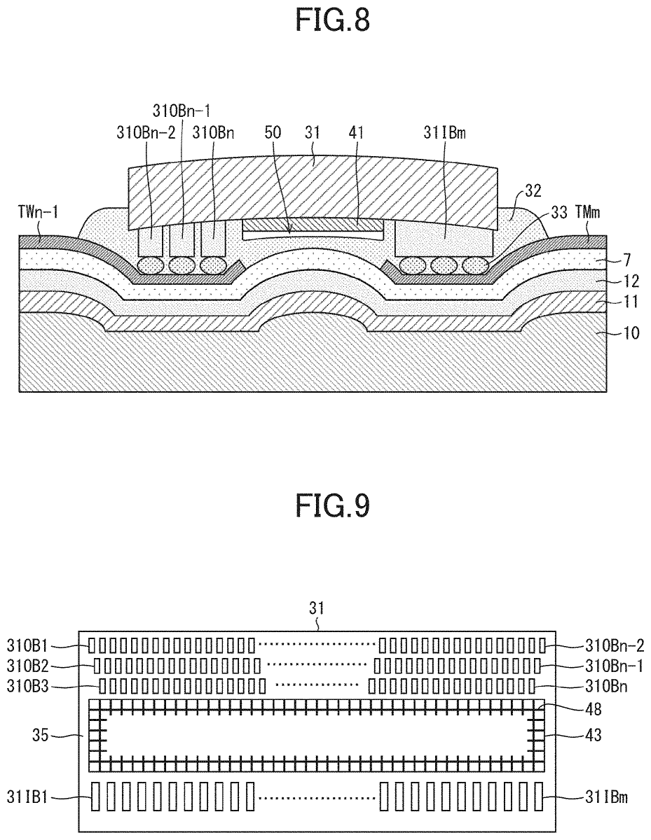

FIG. 8 shows a case where the drive chip 31, according to the first embodiment and coated with the resin film 41, is subjected to a reliability test.

As described above with reference to FIG. 7, when the drive chip 31 is deformed to curve concavely, the drive chip 31 exhibits a force to revert to the original flat form (resilience). When this resilience exceeds the adhesiveness between the anisotropic conductive film 32 and the drive chip 31, delamination 50 could appear between the resin film 41 and the anisotropic conductive film 32.

When the delamination 50 appears, an increasing number of particles are flattened in the anisotropic conductive material 33 found between the input terminals 31IB1 to 31IBm and the output signal input lines TM1 to TMm. When the increasing number of particles are flattened in the anisotropic conductive material 33, a resistance value increases, possibly causing poor electrical connection between the input terminals 31IB1 to 31IBm and the output signal input lines TM1 to TMm. Simultaneously, when the delamination 50 appears, an increasing number of particles are flattened in the anisotropic conductive material 33 found between the output terminals 31OB1 to 31OBn and the routed lines TW1 to TWn. When the increasing number of particles are flattened in the anisotropic conductive material 33, a resistance value increases, possibly causing poor electrical connection between the output terminals 31OB1 to 31OBn and the routed lines TW1 to TWn.

Here, the resin film 42 according to the second embodiment is provided with the texture 48 formed across the whole surface of the resin film 42 (see FIG. 5). The texture 48 exhibits the anchor effect. In the anchor effect, the adhesive spreads into pores or cracks on a surface of a material to be bonded, and solidifies in the pores or the cracks to enhance its adhesion strength. This anchor effect can improve the adhesiveness between the resin film 42 and the anisotropic conductive film 32. As a result, the improved adhesiveness can reduce the risk of delamination between the resin film 42 and the anisotropic conductive film 32, and the occurrence of the poor electrical connection. In addition, as can be seen in the case of the resin film 41, the circuit face 35 of the drive chip 31 is protected from a foreign object by the resin film 42.

Thanks to the above features, the resin film 42 can contribute to providing the flexible organic EL display device 1 with highly reliable electrical connection.

### Third Embodiment

FIG. 9 is a schematic view of the resin film 43 according to a third embodiment. As illustrated, the resin film 43 is provided between the input terminals 31IB1 to 31IBm and the output terminals 31OB1 to 31OBn, in order to keep the circuit face 35 of the drive chip 31 from having a scratch due to an incoming foreign object. The resin film 43 has the texture 48 provided only to an outer periphery of the resin film 43 in plan view.

Usually, the resin film and the anisotropic conductive film would be likely to delaminate at the outer periphery of the resin film. Thus, the resin film 43 has the texture 48 formed only on its outer periphery that the delamination is likely to occur. Thanks to such a feature, the resin film 43 achieves advantageous effects below.

First, the resin film 43 achieves the same advantageous effects as those of the resin film 42 according to the second embodiment. Moreover, the resin film 43 is provided with less texture 48 than the resin film 42 is. Thanks to such a feature, the resin film 43 can keep a foreign object from entering the texture 48, and reduce production costs.

### Fourth Embodiment

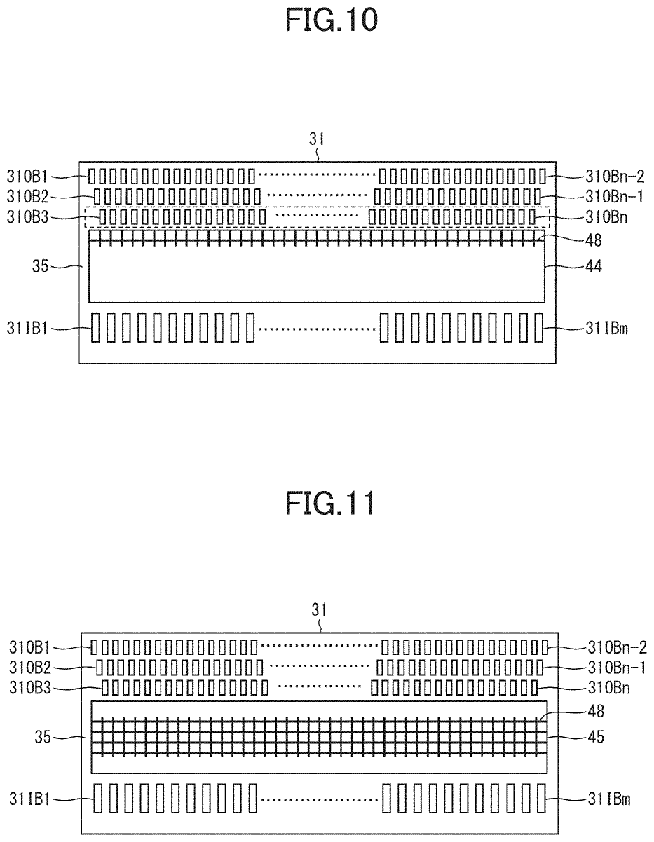

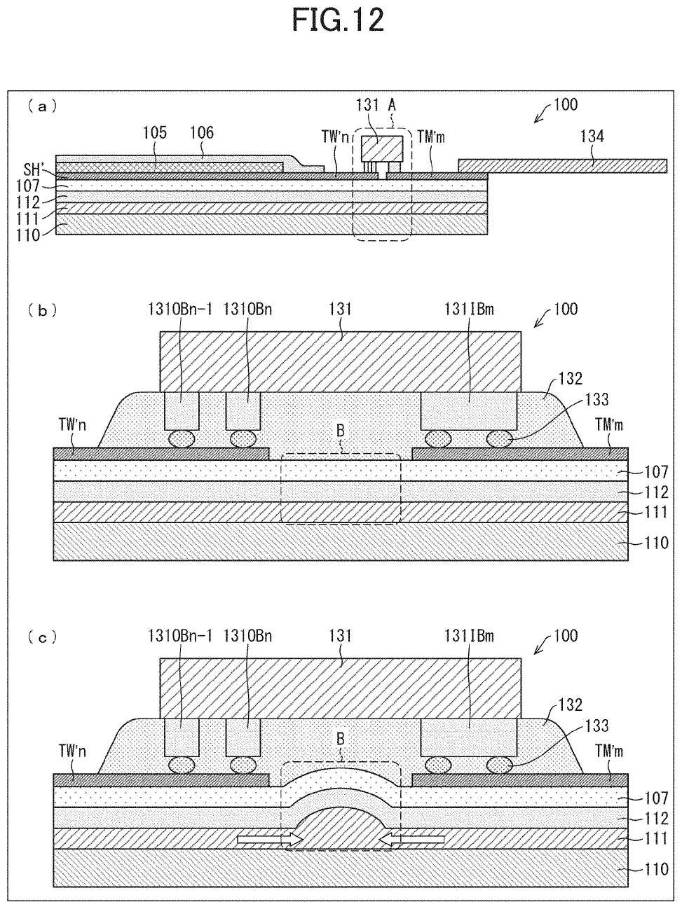

FIG. 10 is a schematic view of the resin film 44 according to a fourth embodiment. As illustrated, the resin film 44 is provided between the input terminals 31IB1 to 31IBm and the output terminals 31OB1 to 31OBn, in order to keep the circuit face 35 of the drive chip 31 from having a scratch due to an incoming foreign object. As illustrated in FIG. 10, the output terminals 31OB1 to 31OBn of the drive chip 31 are arranged in three rows. Moreover, the output terminals 31OB3 to 31OBn in a row closest to the resin film 44 are enclosed with a broken line. The resin film 44 has the texture 48 formed only in the vicinity of the output terminals 31OB3 to 31OBn.

This is because, among the output terminals of the drive chip 31, the output terminals 31OB3 to 31OBn are most likely to cause poor electrical connection, and the poor electrical connection among the output terminals 31OB3 to 31OBn is to be reduced. Thanks to such a feature, the resin film 44 achieves advantageous effects below.

First, the resin film 44 achieves the same advantageous effects as those of the resin film 43 according to the third embodiment. Moreover, the resin film 44 is provided with less texture 48 than the resin film 43 is. Thanks to such a feature, the resin film 44 can keep a foreign object from entering the texture 48, and reduce production costs.

Note that, if the input terminals 31IB1 to 31IBm are likely to cause poor electrical connection, the resin film 44 may have the texture 48 only in the vicinity of the input terminals 31IB1 to 31IBm. Furthermore, if the output terminals 31OB3 to 31OBn and the input terminals 31IB1 to 31IBm are likely to cause poor electrical connection, the resin film 44 may have the texture 48 provided only to an end of the output terminals 31OB3 to 31OBn and an end of the input terminals 31IB1 to 31IBm.

### Fifth Embodiment

FIG. 11 is a schematic view of the resin film 45 according to a fifth embodiment. As illustrated, the resin film 45 is provided between the input terminals 31IB1 to 31IBm and the output terminals 31OB1 to 31OBn, in order to keep the circuit face 35 of the drive chip 31 from having a scratch due to an incoming foreign object. The resin film 45 has the texture 48 provided only in a center of the resin film 45. The center means an intermediate portion and its surroundings between the input terminals 31IB1 to 31IBm and the output terminals 31OB3 to 31OBn of the drive chip 31. Such a feature is effective when the resin film 45 and the anisotropic conductive film 32 are likely to delaminate in the above center.

Using the resin film 45 as an example, a resin film according to this embodiment can adjust the position of the texture as appropriate.

First Aspect

A display device includes: a flexible substrate; a thin-film transistor layer provided above the flexible substrate; a light-emitting element layer including a first electrode, a functional layer, and a second electrode; a sealing layer; a display region including a plurality of pixels; a frame region provided around the display region; and an electronic component mounted in the frame region.

The electronic component includes: a plurality of input bumps inputting signals; and a plurality of output bumps outputting the signals. The input bumps and the output bumps are arranged in a longitudinal direction of the electric component.

The frame region includes: a plurality of input terminal electrodes each electrically connected to a corresponding one of the input bumps through an anisotropic conductive film; and a plurality of output terminal electrodes each electrically connected to a corresponding one of the output bumps through the anisotropic conductive film.

The electronic component includes a resin film provided toward the flexible substrate between the input bumps and the output bumps. The resin film is rectangular in plan view.

Second Aspect

In the display device according to, for example, the first aspect, the resin film includes a plurality of protrusions shaped into islands in plan view.

Third Aspect

In the display device according to, for example the second aspect, the protrusions are provided over a whole surface of the resin film.

Fourth Aspect

In the display device according to, for example the second aspect, the protrusions are provided only to an outer periphery of the resin film in plan view.

Fifth Aspect

In the display device according to, for example, the fourth aspect, the protrusions are provided only to: an end of the resin film toward the input bumps; and an end of the resin film toward the output bumps in plan view.

Sixth Aspect

In the display device according to, for example the second aspect, the protrusions are provided only in a center of the resin film in plan view.

Seventh Aspect

In the display device according to, for example, the second aspect, the output terminal electrodes are greater in number, and smaller in size in plan view, than the input terminal electrodes, and, in the electronic component, the protrusions are provided only to an end of the resin film toward the output bumps in plan view.

Eighth Aspect

In the display device according to, for example, any one of the second to seventh aspects, each of the protrusions has a protrusion length, from a body of the resin film, of ½ as long as a film thickness of the resin film.

Ninth Aspect

In the display device according to, for example, any one of the first to eighth aspects, the resin film and the anisotropic conductive film adhere to each other by an anchor effect.

Tenth Aspect

In the display device according to, for example, any one of the first to eighth aspects, the resin film is formed of polyimide resin or acrylic resin.

Eleventh Aspect

The display device according to, for example, any one of the first to tenth aspects further includes a resin film attached, through an adhesive layer, to a surface of the flexible substrate across from the thin-film transistor.

### Summary

An electro-optical element (an electro-optical element whose luminance and transmittance are controlled by current) included in an electronic device according to the embodiments may be any given electro-optical element. Examples of the display device according to the embodiments include: an organic EL display including organic light-emitting diodes (OLEDs) as electro-optical elements; an inorganic EL display including inorganic light-emitting diodes as electro-optical elements; and a quantum dot light-emitting diode (QLED) display including QLEDs.

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined to achieve a new technical feature.

1. A display device, comprising:
a flexible substrate; a thin-film transistor layer provided above the flexible substrate; a light-emitting element layer including at least one first electrodes, at least one functional layer, and at least one second electrode; a sealing layer; a display region including a plurality of pixels; a frame region provided around the display region; and an electronic component mounted in the frame region, wherein:
the electronic component including: a plurality of input bumps inputting a plurality of input signals; and a plurality of output bumps outputting a plurality of output signals, the input bumps and the output bumps being arranged in a longitudinal direction of the electric component,
the frame region including: a plurality of input terminal electrodes each electrically connected to a corresponding one of the input bumps through an anisotropic conductive film; and a plurality of output terminal electrodes each electrically connected to a corresponding one of the output bumps through the anisotropic conductive film, and
the electronic component including a resin film provided toward the flexible substrate between the input bumps and the output bumps, the resin film being rectangular in plan view.

2. The display device according to claim 1, wherein
the resin film includes a plurality of protrusions in a thickness direction, the plurality of protrusions are protrude from a body of the resin film and shaped into islands in plan view.

3. The display device according to claim 2, wherein
in plan view, the protrusions are provided over a whole surface of the resin film.

4. The display device according to claim 2, wherein
in plan view, the protrusions are provided only to an outer periphery of the resin film.

5. The display device according to claim 4, wherein
in plan view, the protrusions are provided only to: an end of the resin film toward the input bumps; and an end of the resin film toward the output bumps.

6. The display device according to claim 2, wherein
in plan view, the protrusions are provided only in a center of the resin film.

7. The display device according to claim 2, wherein
the output terminal electrodes are greater in number, and smaller in size in plan view, than the input terminal electrodes, and, in the electronic component, the protrusions are provided only to an end of the resin film toward the output bumps in plan view.

8. The display device according to claim 2, wherein:
each of the protrusions has a protrusion length, from the body of the resin film, of ½ as long as a film thickness of the resin film.

9. The display device according to claim 1, wherein
the resin film and the anisotropic conductive film adhere to each other by an anchor effect.

10. The display device according to claim 1, wherein
the resin film is formed of polyimide resin or acrylic resin.

11. The display device according to claim 1, further comprising
a resin film attached, through an adhesive layer, to a surface of the flexible substrate opposite to a surface where the thin-film transistor layer is provided.
